(19) United States
(12) Patent Application Publication
(10) Pub. No.: US 2002/0132424 A1
(43) Pub. Date: Sep. 19, 2002

(54) Semiconductor devices having a non-volatile memory transistor and methods for manufacturing the same

(76) Inventor: Tomoyuki Furuhata, Sakata-shi (JP)

Correspondence Address: KONRAD RAYNES VICTOR & MANN, LLP, 315 SOUTH BEVERLY DRIVE, SUITE 210, BEVERLY HILLS, CA, 90212, US

(21) Appl. No.: 10/011,724

(22) Filed: Dec. 11, 2001

(30) Foreign Application Priority Data
Dec. 11, 2000 (JP) 2000-376044(P)

(51) Int. Cl. H01L 21/336

(52) U.S. Cl. 438/257

(57) ABSTRACT

Semiconductor devices including a non-volatile memory transistor and methods for manufacturing the same, are described. One method for manufacturing a semiconductor device having a non-volatile memory transistor may include forming a silicon oxide layer 20 and a polysilicon layer 22a over a semiconductor substrate 10; forming a second insulating layer 24 over a specified region of the polysilicon layer 22a; forming a floating gate 22 by patterning the polysilicon layer 22a; removing at least a side end section of the second insulating layer 24; forming a silicon oxide layer 26 that contacts at least a part of a peripheral section of the floating gate 22; forming a control gate 28 having a specified pattern over the silicon oxide layer 26; and forming an impurity diffusion layer 14, 16 that forms a source region and a drain region in the silicon substrate 10.

Applicant hereby incorporates by reference Japanese Application No. 2000-376044, filed Dec. 11, 2000, in its entirety.

### TECHNICAL FIELD

The present invention relates to semiconductor devices including a non-volatile memory transistor and methods for manufacturing the same.

### RELATED ART

A transistor having a split-gate structure is known as one of the devices that are applied to an electrically erasable programmable ROM (EEPROM). FIG. 12 schematically shows a cross-sectional view of one example of a conventional semiconductor device including a non-volatile memory transistor with a split-gate structure.

The semiconductor device includes a non-volatile memory transistor having a split-gate structure (hereafter referred to as a “memory transistor”) 300.

The memory transistor 300 has, in the case of an N-type transistor as an example, a source region 14 and a drain region 16 composed of N⁺-type impurity diffusion layers formed in the silicon substrate 10 of P-type, and a first insulating layer 70 as a gate insulating layer formed on a surface of the silicon substrate 10. A floating gate 72, a third insulating layer 76 and a control gate 78 are successively formed on the first insulating layer 70.

A second insulating layer 74 is formed on the floating gate 72. The second insulating layer 74 is composed of an insulating layer that is formed by selectively oxidizing a part of a polysilicon layer that becomes the floating gate 72. The second insulating layer 72 has a structure in which the film thickness thereof becomes thinner from its center toward its end sections, as shown in FIG. 12. As a result, upper edge sections 720 of the floating gate 72 form sharp edges, such that an electric field concentration is apt to occur at the upper edge sections 720.

For the operation of the memory transistor with a split-gate structure 300, a channel current is flown between the source region 14 and the drain region 16 to thereby inject a charge (hot electrons) in the floating gate 72 as indicated by an arrow A10 when data is written. When data is erased, a predetermined high voltage is applied to the control gate 78 to thereby transfer the charge stored in the floating gate 72 through the third insulating layer 76 to the control gate 78 as indicated by an arrow B10 by Fowler-Nordheim tunneling conduction (FN conduction).

### SUMMARY

Certain embodiments relate to a method for manufacturing a semiconductor device having a non-volatile memory transistor, the method including the steps of: (a) forming a first insulating layer comprising a gate insulating layer on a semiconductor layer; (b) forming a conductive layer on the first insulating layer; (c) forming a second insulating layer over a specified region of the conductive layer; (d) forming a floating gate under the second insulating layer by patterning the conductive layer; (e) removing a part of the second insulating layer to remove at least a side end section of the second insulating layer and expose an upper surface of a peripheral section of the floating gate; (f) forming a third insulating layer that contacts at least a part of the peripheral section of the floating gate and functions as a tunnel insulating layer; (g) forming a control gate having a specified pattern over the third insulating layer; and (h) forming an impurity diffusion layer that forms a source region and a drain region in the semiconductor layer.

Embodiments also relate to a semiconductor device having a non-volatile memory transistor, including a semiconductor layer and a first insulating layer including a gate insulating layer on the semiconductor layer. The device includes a floating gate provided over the first insulating layer, and a second insulating layer provided over the floating gate. The device also includes a third insulating layer that contacts at least a part of a peripheral section of the floating gate. The device also includes a control gate provided over the third insulating layer. A recessed section is provided in the third insulating layer over the peripheral section of the floating gate.

Embodiments also relate to a semiconductor device having a non-volatile memory transistor, including a semiconductor layer and a gate insulating layer on the semiconductor layer. A floating gate is provided over the gate insulating layer, the floating gate including an upper surface. A second insulating layer is provided over the floating gate, the second insulating layer being in direct contact with a portion of the upper surface of the floating gate. A third insulating layer is positioned in direct contact with part of the upper surface of the floating gate; and a control gate is provided over the third insulating layer.

Embodiments also relate to a method for manufacturing a semiconductor device having a non-volatile memory transistor, the method including forming a first insulation layer on a semiconductor layer and forming a conductive layer on the first insulation layer. A second insulating layer is formed over a specified region of the conductive layer. A floating gate is formed under the second insulating layer by etching the first insulation layer and the conductive layer. At least a side end section of the second insulating layer is removed to expose an upper surface of a peripheral section of the floating gate. A third insulating layer is formed that is in direct contact with at least part of the exposed upper surface of the peripheral section of the floating gate. A control gate having a specified pattern over the third insulating layer is formed.

### BRIEF DESCRIPTION OF THE DRAWINGS

Embodiments of the invention are described with reference to the accompanying drawings which, for illustrative purposes, are schematic and not necessarily drawn to scale.

FIG. 1 schematically shows a cross-sectional view of a semiconductor device in accordance with an embodiment of the present invention.

FIG. 2 shows an enlarged cross-sectional view of a cross section at F10 in FIG. 1.

FIG. 3 shows an illustration for describing the effects of a semiconductor device in accordance with an embodiment of the present invention.

FIG. 4 shows a cross-sectional view of a step for manufacturing the semiconductor device in accordance with an embodiment of the present invention.

FIG. 5 shows a cross-sectional view of a step for manufacturing the semiconductor device in accordance with an embodiment of the present invention.

FIG. 6 shows a cross-sectional view of a step for manufacturing the semiconductor device in accordance with an embodiment of the present invention.

FIG. 7 shows a cross-sectional view of a step for manufacturing the semiconductor device in accordance with an embodiment of the present invention.

FIG. 8 shows a cross-sectional view of a step for manufacturing the semiconductor device in accordance with an embodiment of the present invention.

FIG. 9 shows a cross-sectional view of a step for manufacturing the semiconductor device in accordance with an embodiment of the present invention.

FIG. 10 shows an illustration for describing the effects of a method for manufacturing a semiconductor device in accordance with an embodiment of the present invention.

FIG. 11 schematically shows a layout of an embedded semiconductor device in accordance with an embodiment of the present invention.

FIG. 12 schematically shows a cross-sectional view of a conventional example of a semiconductor device.

FIG. 13 shows a cross-sectional view for describing a layered structure of a silicon oxide layer that functions as a tunneling insulating layer.

### DETAILED DESCRIPTION

Certain embodiments of the present invention relate to a semiconductor device having a non-volatile memory transistor with an improved rewritable number characteristic.

A method for manufacturing a semiconductor device having a non-volatile memory transistor in accordance with an embodiment of the present invention includes the following steps (a)-(h) of:

(a) forming a first insulating layer that functions as a gate insulating layer on a semiconductor layer;

(b) forming a conductive layer on the first insulating layer;

(c) forming a second insulating layer over a specified region of the conductive layer;

(d) forming a floating gate under the second insulating layer by patterning the conductive layer;

(e) removing a part of the second insulating layer to remove at least a side end section of the second insulating layer and expose an upper surface of a peripheral section of the floating gate;

(f) forming a third insulating layer that contacts at least a part of the peripheral section of the floating gate and functions as a tunnel insulating layer;

(g) forming a control gate having a specified pattern over the third insulating layer; and

(h) forming an impurity diffusion layer that forms a source region or a drain region in the semiconductor layer.

In the present embodiment, in step (e), the side end section of the second insulating layer is removed to expose the upper surface of the peripheral section of the floating gate. Accordingly, in step (f), the third insulating layer can be formed in a manner to contact the upper surface of the peripheral section of the floating gate. As a result, when a charge (electrons in particular) is pulled out from the floating gate to the control gate, the width of the insulating layer in a region through which the charge passes can be defined only by the third insulating layer. Therefore, the control of the width of the insulating layer in the region through which the charge passes becomes easier, and variations in the width of the insulating layer can be suppressed. Accordingly, in accordance with the present embodiment, variations in the tunnel current are suppressed, and therefore the rewritable number (endurance characteristic) is improved.

In step (e), the width of the upper surface of the peripheral section of the floating gate to be exposed may be, for example, 1 to 10 nm.

Step (e) may be conducted by an isotropic etching.

The third insulating layer in step (f) may include at least one insulating layer formed by a CVD method. In this case, the third insulating layer may be composed of a plurality of insulating layers, and an intermediate insulating layer among the plurality of insulating layers may be formed by a high-temperature CVD method.

A semiconductor device obtained by the above method for manufacturing a semiconductor device having a non-volatile memory transistor has a structure, for example, as follows.

Namely, a semiconductor device having a non-volatile memory transistor may comprise: a semiconductor layer; a first insulating layer that functions as a gate insulating layer on the semiconductor layer; a floating gate provided over the first gate insulating layer; a second insulating layer provided over the floating gate; a third insulating layer that contacts at least a part of the peripheral section of the floating gate and functions as a tunnel insulating layer; and a control gate provided over the third insulating layer; wherein a recessed section is provided in the third insulating layer over the peripheral section of the floating gate.

The third insulating layer may contact an upper surface of the peripheral section of the floating gate.

The recessed section may have a depth of 1 to 10 nm.

Also, the third insulating layer may include at least one insulating layer formed by a CVD method. More specifically, in certain embodiments, the third insulating layer may be formed of at least three insulating layers, and a lowermost insulating layer that contacts the floating gate and an uppermost layer that contacts the control gate among the at least three layers are formed of thermal oxidation layers.

The semiconductor device having a non-volatile memory transistor in accordance with the present embodiment may further include another circuit region mixed-mounted thereon. The circuit region may include at least a logic circuit.

The following embodiments may be provided when the third insulating layer is formed of at least three insulating layers, and a lowermost insulating layer that contacts the floating gate and an uppermost layer that contacts the control gate among the at least three layers are formed of thermal oxidation layers.

One embodiment further includes another circuit region mix-mounted thereon, in which the circuit region has a region of a first transistor including a transistor that operates at a first voltage level, and a gate insulating layer of the first transistor is formed in the same step in which the uppermost insulating layer is formed. In this embodiment, the circuit region may have a region of a second transistor including a transistor that operates at a second voltage level, and a gate insulating layer of the second transistor may be formed in the same step in which the third insulating layer is formed. It is noted that an absolute value of the first voltage level may be small compared to an absolute value of the second voltage level.

It is noted that the “semiconductor layer” may include a semiconductor substrate and a semiconductor layer formed on a substrate.

Certain preferred embodiments of the present invention are described below with reference to the accompanying drawings.

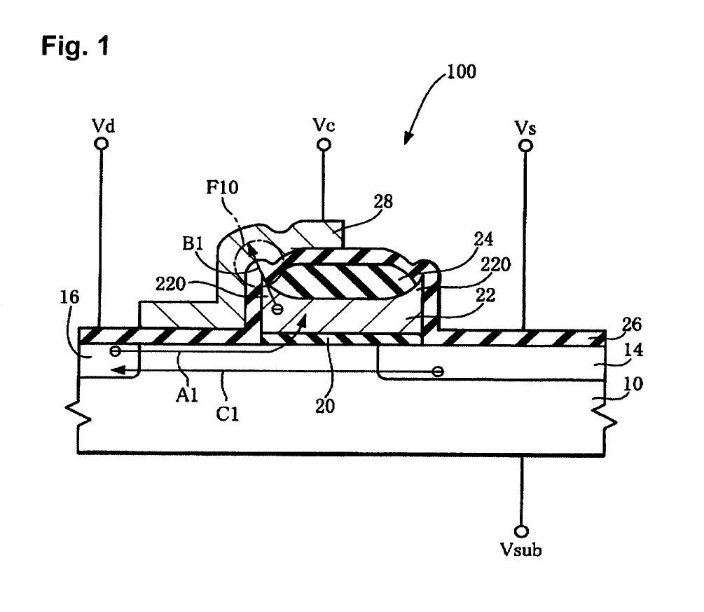

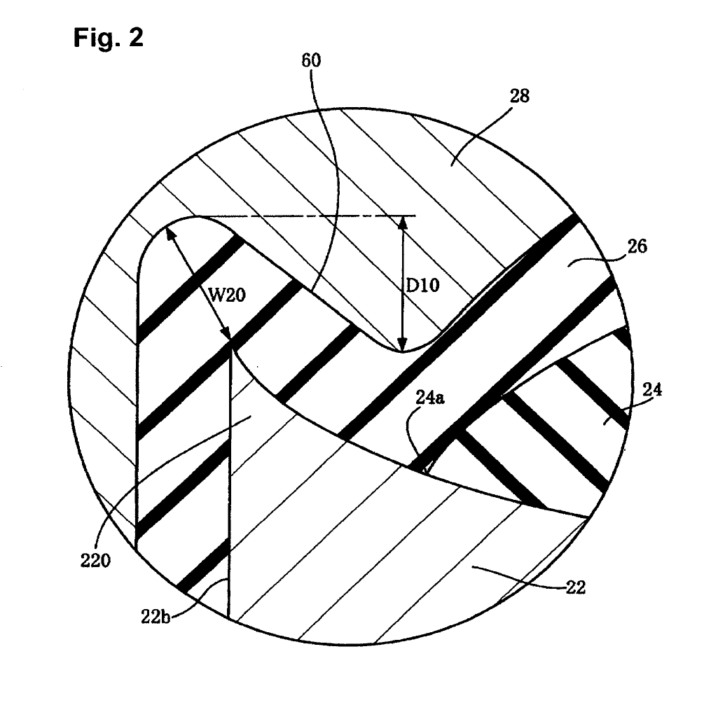

A semiconductor device in accordance with an embodiment is described. FIG. 1 schematically shows a cross-sectional view of a semiconductor device in accordance with the present embodiment. FIG. 2 shows an enlarged cross-sectional view of a cross section at F10 in FIG. 1.

The semiconductor device includes a non-volatile memory transistor having a split-gate structure (hereafter referred to as a “memory transistor”) 100. The memory transistor 100 has a source region 14, a drain region 16 and a first insulating layer 20 that functions as a gate insulating layer. The source region 14 and the drain region 16 are composed of N⁺-type impurity diffusion layers formed in the silicon substrate 10 of P-type, in the case of an N-type transistor as an example. The first insulating layer 20 is formed on a surface of the silicon substrate 10.

A floating gate 22, and a second insulating layer 24 are successively formed on the first insulating layer 20. The second insulating layer 24 has a structure in which the thickness thereof becomes thinner from its center toward its end section. As a result, upper sections of peripheral sections 220 of the floating gate 22 form sharp edges, such that an electric field concentration is apt to occur at the upper sections of the peripheral sections 220 of the floating gate 22. As shown in FIG. 2, a side end 24a of the second insulating layer 24 is located inside a side wall 22b of the floating gate. In other words, the peripheral sections 220 of the floating gate 22 protrude outwardly from the side end 24a of the second insulating layer 24. More specifically, an upper surface of the peripheral sections 220 of the floating gate 22 is not covered by the second insulating layer 24.

A third insulating layer 26 is formed in a manner to cover an upper surface of the second insulating layer 24, a side surface of the floating gate 22 and a surface of the silicon substrate 10. The third insulating layer 26 functions as a so-called tunneling insulating layer. The third insulating layer 26 contacts an upper surface of the peripheral section 220 of the floating gate 22, as shown in FIG. 2. This allows the peripheral section 220 of the floating gate 22 to be covered by the third insulating layer 26. As a result, the thickness W20 of the tunneling insulating layer in a region through which the charge passes is determined only by the third insulating layer 26.

Also, the third insulating layer 26 is recessed in an upper portion of the peripheral section 220 of the floating gate 22. For example, as seen in FIG. 2, concave section 60 is provided in the upper portion of the third insulating layer 26 on the peripheral section of the floating gate 22. The concave section 60 has a depth D10 that is for example, 1 to 10 nm.

A control gate 28 is formed on an upper surface of the third insulating layer 26. A silicide layer may be formed on the control gate 28 depending on the requirements. For example, tungsten silicide, molybdenum silicide, titanium silicide, and cobalt silicide can be listed as a material for the silicide layer.

The control gate 28 may be connected to a word line, the source region 14 may be connected to a source line and the drain region 16 may be connected to a bit line.

Next, a method for operating the memory transistor 100 that comprises the semiconductor device in accordance with one example of the present embodiment will be described with reference to FIG. 1.

Referring to FIG. 1, Vc indicates a voltage applied to the control gate 28, Vs indicates a voltage applied to the source region 14, Vd indicates a voltage applied to the drain region 16, and Vsub indicates a voltage applied to the P-type silicon substrate 10.

For the operation of the memory transistor 100, a channel current is flown between the source region 14 and the drain region 16 to thereby inject a charge (hot electrons) in the floating gate 22 when data is written. When data is erased, a predetermined high voltage is applied to the control gate 28 to thereby transfer the charge stored in the floating gate 22 to the control gate 28 by FN conduction. Each of the operations in one example will be described below.

First, the data-writing operation will be described. It is noted that an arrow A1 indicates a flow of electrons at the time of writing.

For the data-writing operation, the source region 14 is set at a higher potential with respect to the drain region 16, and a specified potential is applied to the control gate 28 depending on the requirements. As a result, hot electrons that are generated near the drain region 16 are accelerated toward the floating gate 22, and injected in the floating gate 22 through the first insulating layer 20 whereby data is written.

In the data-writing operation, for example, the control gate 28 is set at a potential (Vc) of 2 V, the source region 14 is set at a potential (Vs) of 10.5 V, and the drain region 16 is set at a potential (Vd) of 0.8 V. Also, the silicon substrate 10 is set at a potential (Vsub) of 0 V.

Next, the data-erasing operation will be described. It is noted that an arrow B1 indicates a flow of electrons at the time of erasing.

For the data-erasing operation, the control gate 28 is set at a potential higher than the potential of the source region 14 and the drain region 16. As a result, the charge stored in the floating gate 22 is discharged from the upper section of the peripheral section 220 of the floating gate 22, passing through the third insulating layer 26, to the control gate 28 by FN conduction, whereby the data is erased.

In the data-erasing operation, for example, the control gate 28 is set at a potential (Vc) of 11.5 V, the source region 14 and the drain region 16 are set at potentials (Vs) and (Vd) of 0 V, respectively. The silicon substrate 10 is set at a potential (Vsub) of 0 V.

Next, the data-reading operation will be described. It is noted that an arrow C1 indicates a flow of electrons at the time of reading.

For the data-reading operation, the drain region 16 is set at a higher potential than the source region 14, and a predetermined potential is applied to the control gate 28, whereby a determination is made whether or not data is written based on the presence or the absence of a formed channel. More specifically, when a charge is injected in the floating gate 22, the potential of the floating gate 22 becomes low, with the result that a channel is not formed, and a drain current does not flow. Conversely, when the floating gate 22 is not injected with a charge, the floating gate 22 has a high potential, with the result that a channel is formed, and a drain current flows. By detecting a current flowing from the drain region 16 by a sense amplifier, data in the memory transistor 100 can be read out.

In the data-reading operation, for example, the control gate 28 is set at a potential (Vc) of 3.0 V, the source region 14 is set at a potential (Vs) of 0 V, and the drain region 16 is set at a potential (Vd) of 1 V. The silicon substrate 10 is set at a potential (Vsub) of 0 V.

Certain effects which may be present for the semiconductor device in accordance with the present embodiment are described below.

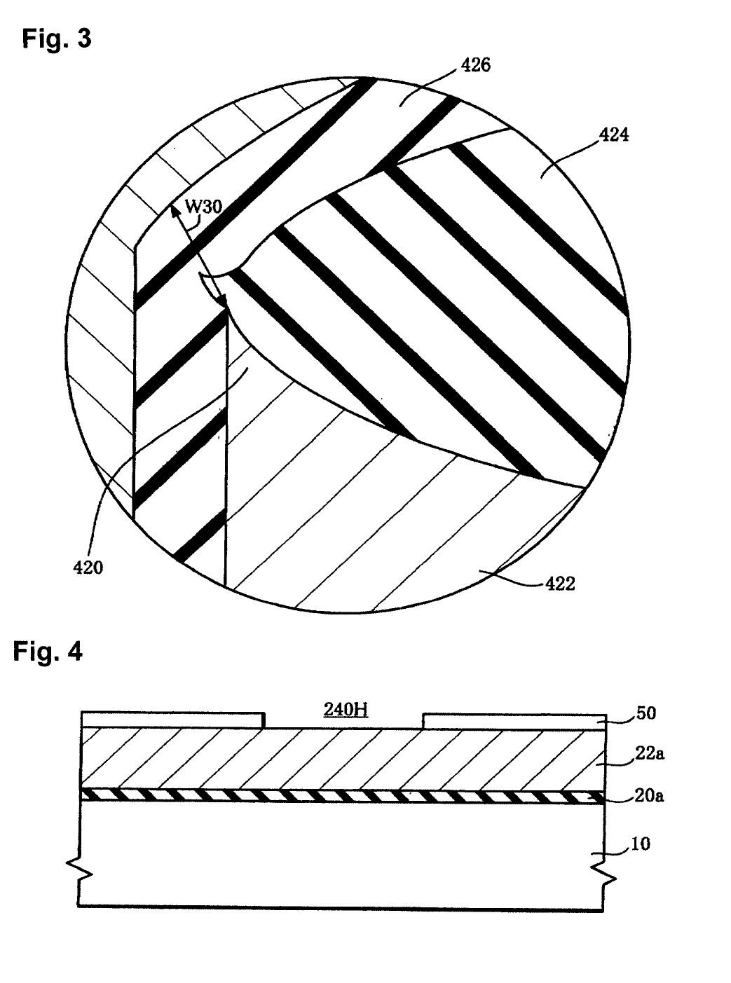

As shown in FIG. 3, the case where the upper surface of a peripheral section 420a of a floating gate 422 is entirely covered by a second insulating layer 424 is conceivable. For example, when an etching is conducted to form the floating gate 422 using the second insulating layer 424 as a mask, an undercut may be created due to unstable conditions. When an undercut is created, an end of the third insulating layer 424 outwardly protrudes from the side surface of the floating gate 422 as shown in FIG. 3. In this case, the width W30 of the insulating layer in a region where the charge passes through is determined by the second insulating layer 424 and a third insulating layer 426. Accordingly, the thickness W30 of the insulating layer in a region where the charge passes through is difficult to control.

However, in accordance with the present embodiment, the third insulating layer 26 contacts the upper surface of the peripheral section of the floating gate 22. Accordingly, the peripheral section 220 of the floating gate is covered by the third insulating layer 26. As a result, the width W20 of the insulating layer in a region where the charge passes through is determined only by the third insulating layer 26. Therefore, in accordance with the present embodiment, the width W20 of the insulating layer in a region where the charge passes through becomes easier to control. Accordingly, in accordance with the present embodiment, variations in the tunnel current are suppressed, and therefore the rewritable number (endurance characteristic) is improved.

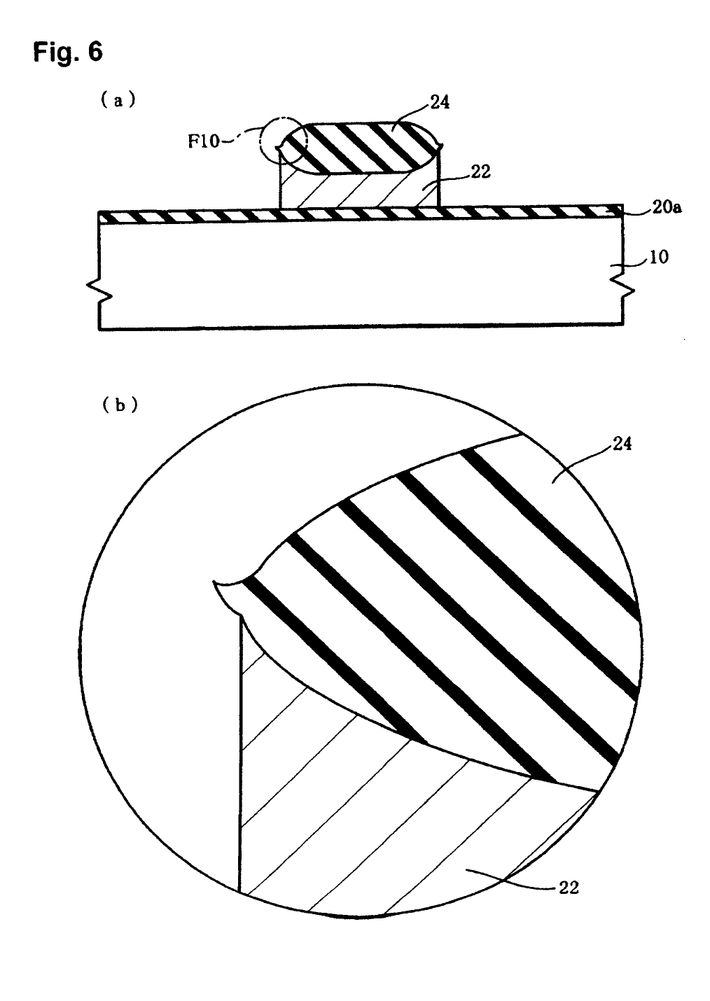

A method for manufacturing the semiconductor device in accordance with one embodiment of the present invention will be described. FIGS. 4 through 9 schematically show cross sections of a semiconductor device in manufacturing steps in accordance with this embodiment. In each of FIGS. 6 through 8, (b) schematically shows an enlarged cross section of a portion F10 in (a).

As shown in FIG. 4, a silicon oxide layer (first insulating layer) 20a is formed on a surface of the silicon substrate 10. The silicon oxide layer 20a may be formed by, for example, a thermal oxidation method. The silicon oxide layer 20a is not limited to a specific thickness, but may preferably have a thickness of 7 to 9 nm in view of the gate insulating strength, the data retaining characteristic and the like.

Then, a polysilicon layer (conductive layer) 22a is formed on a surface of the silicon oxide layer 20a, and phosphorous or arsenic is diffused in the polysilicon layer 22a to form an N-type polysilicon layer 22a. The method for forming the polysilicon layer 22a is not particularly limited, and a CVD method may be used. The polysilicon layer 22a may preferably be formed to have a thickness of, for example, 50 to 300 nm, and more preferably 100 to 200 nm.

The polysilicon layer 22a may be changed to N-type by other methods. For example, after the polysilicon layer 22a is formed, phosphorous ions or arsenic ions are implanted therein. Alternatively, after the polysilicon layer 22a is formed, it is contacted with a carrier gas containing phosphoryl chloride (POCl₃). Alternatively, when the polysilicon layer 22a is formed, it is contacted with a carrier gas containing phosphine (PH₃).

Then, a silicon nitride layer 50 is formed on a surface of the polysilicon layer 22a by, for example, a CVD method. Next, using a lithography technique, specified regions of the silicon nitride layer 50 are selectively etched and removed. A region 240H of the silicon nitride layer 50 that is removed is a region where a second insulating layer 24 of the memory transistor 100 is formed.

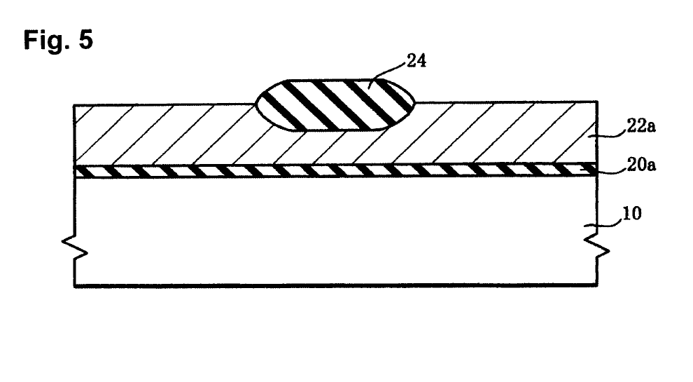

Next, as shown in FIG. 5, an exposed portion of the polysilicon layer 22a is selectively oxidized to form a second insulating layer 24 on a surface of the polysilicon layer 22a in a specified region thereof. The second insulating layer 24 formed by the selective oxidation has a structure in which it has a maximum film thickness at its central area and gradually becomes thinner toward end sections thereof. Thereafter, the silicon nitride layer 50 is removed.

Then, as shown in FIG. 6, an etching is conducted with the second insulating layer 24 as a mask to pattern the polysilicon layer 22a. As a result, a floating gate 22 is formed.

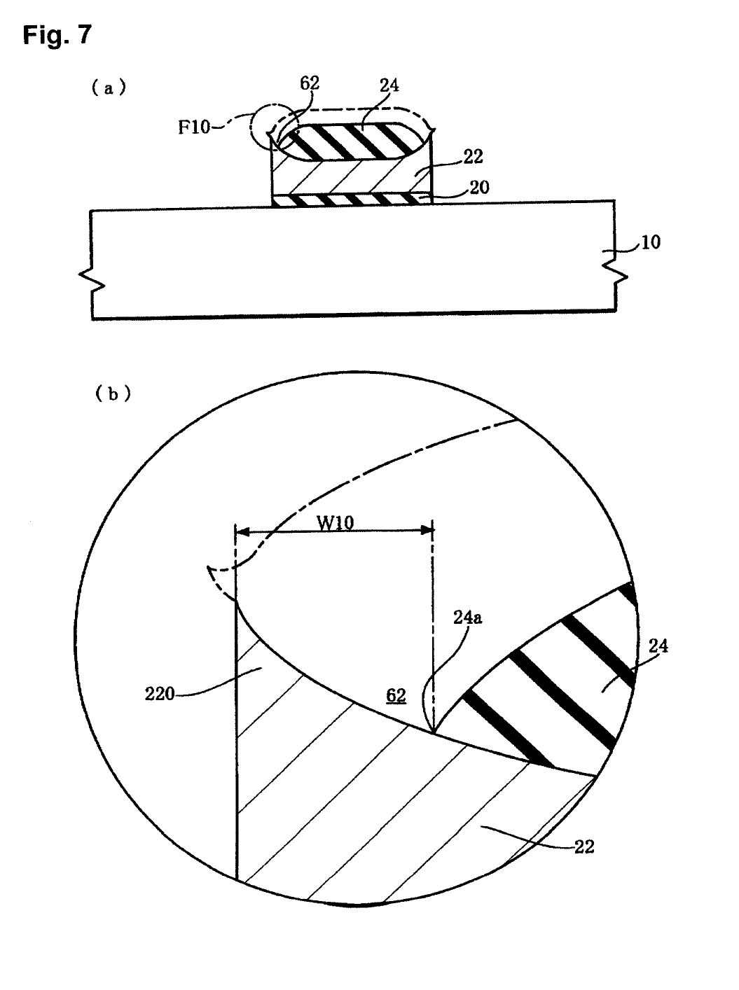

Then, as shown in FIG. 7, the second insulating layer 24 is partially etched, to remove side end sections of the second insulating layer 24 such that a side end 24a of the second insulating layer 24 recedes, and at the same time, the silicon oxide layer 20a on the silicon substrate 10 is selectively removed to yield silicon oxide layer 20 (gate oxide). This allows an upper surface of the peripheral section 220 of the floating gate 22 to be exposed. As a result, a recess 62 that is defined by an upper surface of the peripheral section 220 of the floating gate 22 and an upper surface of the second insulating layer 24 is formed. The method of etching the side end section of the second insulating layer 24 is not particularly limited, but an isotropic etching method may preferably be used. A wet etching may be listed as a specific example of the isotropic etching. For example, diluted ammonium fluoride and diluted hydrofluoric acid may be used as an etchant for the wet etching. The width W10 of the exposed upper surface of the peripheral section 220 of the floating gate 22 may be, for example, 1 to 10 nm, and more preferably, 3 to 7 nm.

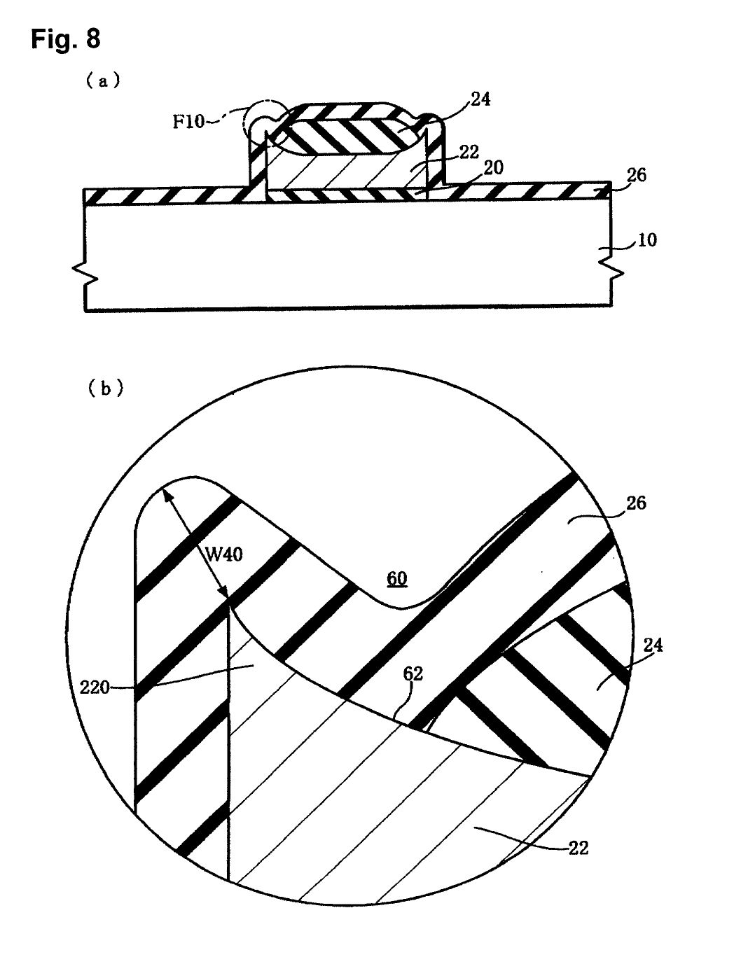

Next, as shown in FIG. 8, a silicon oxide layer (third insulating layer) 26 is deposited on the silicon substrate 10. Because the recess 62 is formed, the silicon oxide layer 26 forms a concave section 60 over the recess 62. Also, the silicon oxide layer 26 contacts the upper surface of the peripheral section 220 of the floating gate 22. Accordingly, the width W40 of the insulating layer in a region where the charge passes through is determined only by the thickness of the silicon oxide layer 26.

The thickness of the silicon oxide layer 26 is, for example, 20 to 25 nm measured from the upper surface of the silicon substrate 10 as a reference. The silicon oxide layer 26 may be formed by any method, for example, a thermal oxidation method, or a CVD method. The silicon oxide layer 26 may preferably be formed by a CVD method. By the CVD method, a sharp edge configuration at the upper section of the peripheral section 220 of the floating gate 22 can be securely maintained. A preferred CVD method is a high-temperature CVD method (for example, a silane-base high-temperature CVD method). Forming the silicon oxide layer 26 by a high-temperature CVD method provides an advantage in that the film quality of the silicon oxide layer 26 becomes dense. When the silicon oxide layer 26 is composed of a silicon oxide layer that is formed by a high-temperature CVD method, its thickness is, for example, 20 to 25 nm.

Also, the silicon oxide layer 26 may be formed of a plurality of layers stacked in layers. More specifically, the silicon oxide layer 26 may have a two-layer structure including a silicon oxide layer obtained by a thermal oxidation method and a silicon oxide layer obtained by a CVD method (for example, a high-temperature CVD method). It is noted that the silicon oxide layer obtained by a thermal oxidation method may be a lower layer, and the silicon oxide layer obtained by a CVD method may be an upper layer, or they may be inversely located. When the silicon oxide layer has a two-layer structure, the thickness of the silicon oxide layer obtained by a thermal oxidation method is, for example, 5 to 15 nm, and the thickness of the silicon oxide layer obtained by a CVD method is, for example, 10 to 20 nm.

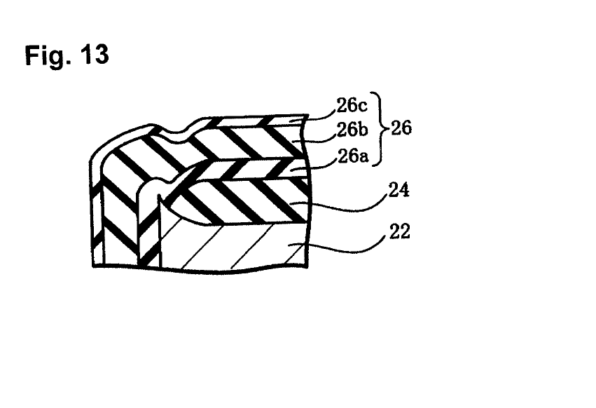

Also, the silicon oxide layer 26 may have a three-layer structure, as illustrated in FIG. 13, for example, including a first silicon oxide layer (thermal oxidation film) 26a that is obtained by a thermal oxidation method, a second silicon oxide layer (HTO film) 26b that is obtained by a high-temperature CVD method, and a third silicon oxide layer (thermal oxidation layer) 26c that is obtained by a thermal oxidation method. In this case, the thickness of the first silicon oxide layer 26a is, for example, 5 to 15 nm, the thickness of the second silicon oxide layer 26b is, for example, 10 to 20 nm, and the thickness of the third silicon oxide layer 26c is, for example, 1 to 5 nm.

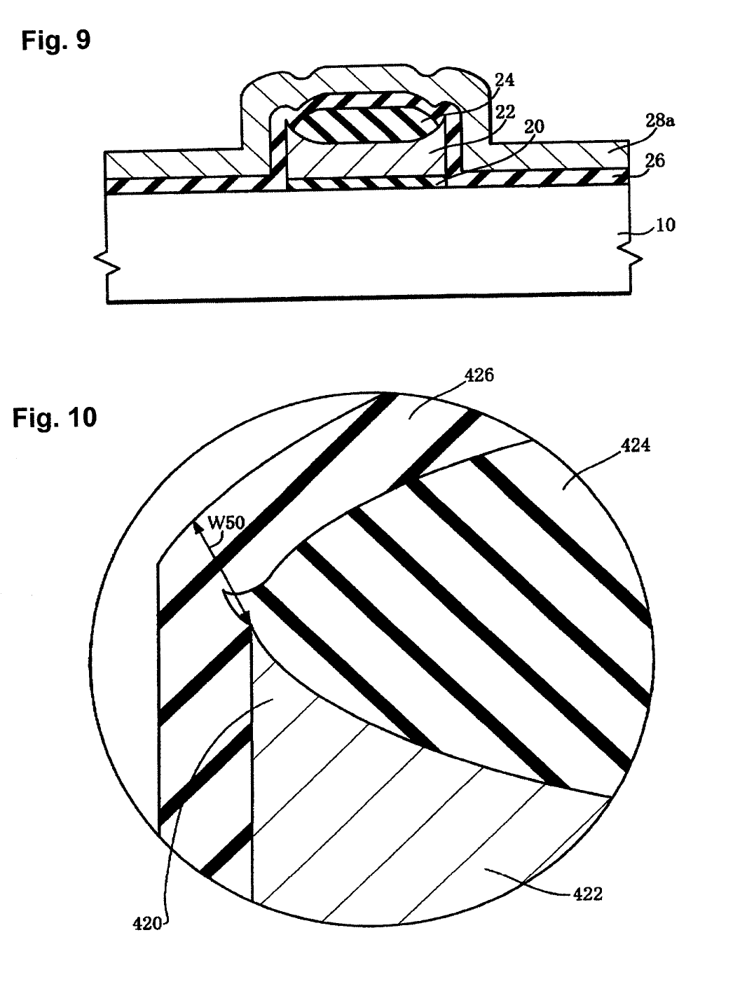

Next, as shown in FIG. 9, a polysilicon layer 28a is formed on a surface of the silicon oxide layer 26. The polysilicon layer 28a may be formed by any method, for example, by a CVD method. The polysilicon layer 28a may be changed to N-type by the same method as conducted for the polysilicon layer 22a described above. The film thickness of the polysilicon layer 28a is, for example, 50 to 300 nm.

Next, a silicide layer may be formed on the polysilicon layer 28a, depending on the requirements. The silicide layer may be formed by, for example, a sputtering method or a CVD method.

Next, a resist layer having a specified pattern is formed on the control gate 28. Then, the polysilicon layer 28a is patterned by an etching. In the manner described above, the control gate 28 is formed as shown in FIG. 1.

Next, an N-type impurity is doped in the silicon substrate 10 by a known method to thereby form a source region 14 and a drain region 16, as shown in FIG. 1.

By the steps described above, the memory transistor 100 shown in FIG. 1 may be formed.

Effects which may be provided by the method for manufacturing a semiconductor device in accordance with the embodiment described above are described below.

As shown in FIG. 10, the silicon oxide layer 426 may be formed without removing the side end section of the second insulating layer 424. However, by such a method, the width W50 of the insulating layer in a region where the charge passes through is determined by the second insulating layer 424 and the silicon oxide layer 426. Accordingly, it is difficult to control the thickness W50 of the insulating layer in a region where the charge passes through.

In contrast, the present embodiment includes the step of removing the side end section of the second insulating layer 24. As a result, an upper surface of the peripheral section 220 of the floating gate 22 is exposed. Accordingly, the silicon oxide layer 26 contacts the upper surface of the peripheral section 220 of the floating gate 22. As a result, the width W40 of the insulating layer in a region where the charge passes through can be formed only by the silicon oxide layer 26. In other words, the width W40 of the insulating layer in a region where the charge passes through can be defined only by the width of the silicon oxide layer 26. As a result, the width W40 of the insulating layer in a region where the charge passes through becomes easier to control. Accordingly, variations in the width W40 of the insulating layer in a region where the charge passes through can be suppressed. As a consequence, variations in the tunnel current are suppressed, and therefore the rewritable number (endurance characteristic) is improved.

A semiconductor device in accordance with embodiments of the present invention may include other circuit regions. The other circuit regions may include, for example, a logic circuit, an interface circuit, a gate array circuit, a memory circuit (for example, RAM and ROM), circuits, such as a processor (for example, RISC) or a variety of IP (Intellectual Property) macros, other digital circuits and analog circuits.

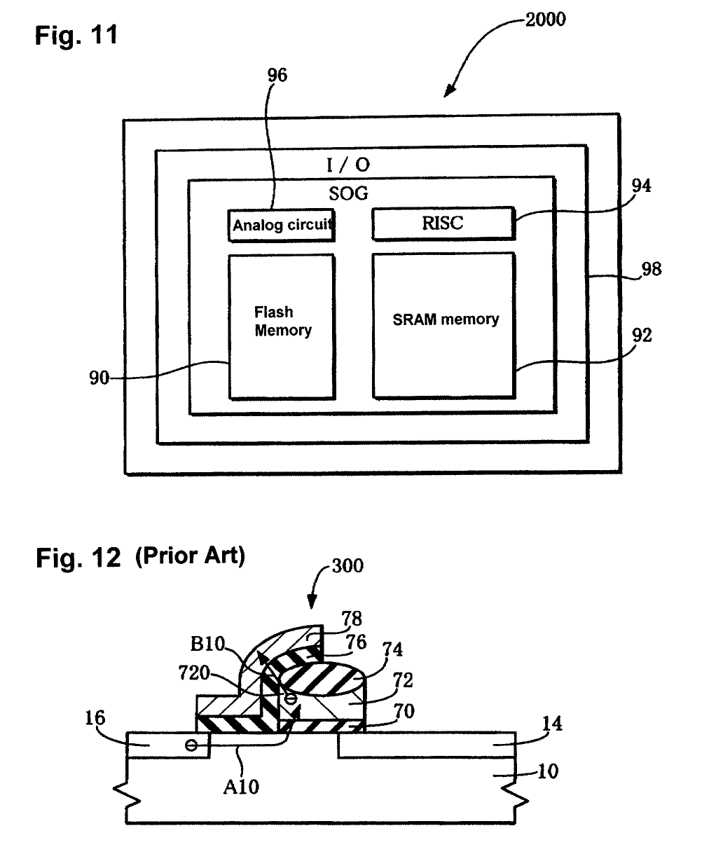

More specifically, in one embodiment, the following embedded semiconductor device is possible. FIG. 11 schematically shows a layout of an embedded semiconductor device in which a semiconductor device in accordance with an embodiment of the present invention is implemented. In this example, the embedded semiconductor device 2000 includes a flash-memory 90, an SRAM memory 92, a RISC 94, an analog circuit 96 and an interface circuit 98 that are mixed and mounted in an SOG (sea of gates). The memory transistor 100 in accordance with the present embodiment is a component of the flash memory 90.

In the embedded semiconductor device embodiment described above, regions of first and second transistor respectively including first and second electric field effect transistors operable at different voltage levels may be formed in circuit regions other than the flash memory 90. For example, the first transistor may be operated at a first voltage level (an absolute value of 1.8 to 3.3 V), and the second transistor may be operated at a second voltage level (an absolute value of 10 to 15 V). When the silicon oxide layer 26 of the memory transistor 100 is formed of three layers including a first silicon oxide layer (thermal oxidation film) 26a, a second silicon oxide layer (HTO film) 26b obtained by a high-temperature CVD method, and a third silicon oxide layer (thermal oxidation layer) 26c, a gate insulating layer of the first transistor can be formed in the same step in which the third silicon oxide layer 26c is formed. Also, a gate insulating layer of the second transistor can be formed in the same step in which the silicon oxide layer 26 is formed.

In this manner, by forming the gate insulating layer of the first transistor with one thermal oxidation film, and the gate insulating layer of the second transistor with thermal oxidation film-HTO film-thermal oxidation film, electric field effect transistors that operate at mutually different operation voltage levels may be formed. Furthermore, these gate insulating layers are formed in the same step in which the third insulating layer 26 of the memory transistor 100 is formed, such that they can be formed with a fewer number of steps.

The present invention is not limited to the embodiments described above, and many modifications can be made without departing the scope of the subject matter of the present invention. For example, the silicon oxide layer 26 may be formed of a plurality of insulating layers greater than three layers.

What is claimed:

1. A method for manufacturing a semiconductor device having a non-volatile memory transistor, the method comprising the steps (a)-(h) of:
(a) forming a first insulating layer comprising a gate insulating layer on a semiconductor layer;
(b) forming a conductive layer on the first insulating layer;
(c) forming a second insulating layer over a specified region of the conductive layer;
(d) forming a floating gate under the second insulating layer by patterning the conductive layer;
(e) removing a part of the second insulating layer to remove at least a side end section of the second insulating layer and expose an upper surface of a peripheral section of the floating gate;
(f) forming a third insulating layer that contacts at least a part of the peripheral section of the floating gate and functions as a tunnel insulating layer;
(g) forming a control gate having a specified pattern over the third insulating layer; and
(h) forming an impurity diffusion layer that forms a source region and a drain region in the semiconductor layer.

2. A method for manufacturing a semiconductor device having a non-volatile memory transistor according to claim 1, wherein, in the step (e), a width of the upper surface of the peripheral section of the floating gate to be exposed is 1 to 10 nm.

3. A method for manufacturing a semiconductor device having a non-volatile memory transistor according to claim 1, wherein the step (e) is conducted by an isotropic etching.

4. A method for manufacturing a semiconductor device having a non-volatile memory transistor according to claim 1, wherein the third insulating layer in the step (f) includes at least one insulating layer formed by a CVD method.

5. A method for manufacturing a semiconductor device having a non-volatile memory transistor according to claim 4, wherein the third insulating layer comprises a plurality of insulating layers, and an intermediate insulating layer among the plurality of insulating layers is formed by a high-temperature CVD method.

6. A semiconductor device having a non-volatile memory transistor, comprising:
a semiconductor layer;
a first insulating layer comprising a gate insulating layer on the semiconductor layer;
a floating gate provided over the first insulating layer;
a second insulating layer provided over the floating gate;
a third insulating layer that contacts at least a part of a peripheral section of the floating gate; and
a control gate provided over the third insulating layer,
wherein a recessed section is provided in the third insulating layer over the peripheral section of the floating gate.

7. A semiconductor device having a non-volatile memory transistor according to claim 6, wherein the third insulating layer contacts an upper surface of the peripheral section of the floating gate, and wherein the third insulating layer functions as a tunnel insulating layer.

8. A semiconductor device having a non-volatile memory transistor according to claim 6, wherein the recessed section has a depth of 1 to 10 nm.

9. A semiconductor device having a non-volatile memory transistor according to claim 6, wherein the third insulating layer includes at least one insulating layer formed by a CVD method.

10. A semiconductor device having a non-volatile memory transistor according to claim 9, wherein the third insulating layer is formed of at least three insulating layers, and a lowermost insulating layer that contacts the floating gate and an uppermost layer that contacts the control gate among the at least three layers are formed of thermal oxidation layers.

11. A semiconductor device having a non-volatile memory transistor according to claim 6, wherein said non-volatile memory transistor is part of a first circuit region, further comprising a second circuit region mixed-mounted therewith.

12. A semiconductor device having a non-volatile memory transistor according to claim 11, wherein the second circuit region includes at least a logic circuit.

13. A semiconductor device having a non-volatile memory transistor according to claim 10, wherein said non-volatile memory transistor is at least part of a first circuit region, further comprising a second circuit region mixed-mounted therewith, wherein the second circuit region has a region of a first transistor including a transistor that operates at a first voltage level, and a gate insulating layer of the first transistor is formed in the same step in which the uppermost insulating layer of the non-volatile memory transistor is formed.

14. A semiconductor device having a non-volatile memory transistor according to claim 13, wherein the second circuit region has a region of a second transistor including a transistor that operates at a second voltage level, and a gate insulating layer of the second transistor is formed in the same step in which the third insulating layer of the non-volatile memory transistor is formed.

15. A semiconductor device having a non-volatile memory transistor according to claim 14, wherein an absolute value of the first voltage level is less than an absolute value of the second voltage level.

16. A semiconductor device having a non-volatile memory transistor, comprising:
a semiconductor layer;
a gate insulating layer on the semiconductor layer;
a floating gate provided over the gate insulating layer, the floating gate including an upper surface;
a second insulating layer provided over the floating gate, the second insulating layer being in direct contact with a portion of the upper surface of the floating gate;
a third insulating layer in direct contact with part of the upper surface of the floating gate; and
a control gate provided over the third insulating layer.

17. A semiconductor device having a non-volatile memory transistor according to claim 16, wherein the third insulating layer extends over the second insulating layer.

18. A semiconductor device having a non-volatile memory transistor according to claim 16, wherein the third insulating layer includes a recess therein that is positioned over a portion of the floating gate.

19. A method for manufacturing a semiconductor device having a non-volatile memory transistor, the method comprising:
forming a first insulation layer on a semiconductor layer;
forming a conductive layer on the first insulation layer;
forming a second insulating layer over a specified region of the conductive layer;
forming a floating gate under the second insulating layer by etching the first insulation layer and the conductive layer;
removing at least a side end section of the second insulating layer to expose an upper surface of a peripheral section of the floating gate;
forming a third insulating layer that is in direct contact with at least part of the exposed upper surface of the peripheral section of the floating gate; and
forming a control gate having a specified pattern over the third insulating layer.

20. A method as in claim 19, further comprising forming the third insulating layer to include a recess therein over a portion of the floating gate.
